(19) United States
(12) Patent Application Publication
(10) Pub. No.: US 2026/0366133 A1
(43) Pub. Date: Nov. 19, 2026

(54) METHOD FOR COATING A SUBSTRATE WITH TETRAGONAL VANADIUM NITRIDE

(71) Applicants: SAFRAN, Paris (FR); CENTRE NATIONAL DE LA RECHERCHE SCIENTIFIQUE, Paris (FR); UNIVERSITE DE BORDEAUX, Bordeaux (FR); INSTITUT POLYTECHNIQUE DE BORDEAUX, Talence (FR)

(72) Inventors: Marjorie Christine Cavarroc, Moissy-Cramayel (FR); Louise Renée Antoine, Moissy-Cramayel (FR); Angéline Nadine Jeanne Poulon, Arsac (FR); Dominique Paul Abel Michau, Pessac (FR)

(73) Assignees: SAFRAN, Paris (FR); CENTRE NATIONAL DE LA RECHERCHE SCIENTIFIQUE, Paris (FR); UNIVERSITE DE BORDEAUX, Bordeaux (FR); INSTITUT POLYTECHNIQUE DE BORDEAUX, Talence (FR)

(21) Appl. No.: 19/476,040

(22) PCT Filed: Apr. 16, 2024
(86) PCT No.: PCT/FR2024/050500

§ 371 Date: Oct. 16, 2025

(30) Foreign Application Priority Data
Apr. 20, 2023 (FR) FR2303986

(51) Int. Cl. C23C 14/06; C23C 14/34; C23C 14/35

(52) U.S. Cl. CPC C23C 14/0641; C23C 14/3414; C23C 14/35

(57) ABSTRACT

A method for coating a substrate With tetragonal vanadium nitride by high-power pulsed magnetron sputtering is disclosed. The method relates to a substrate coated with at least one layer of tetragonal vanadium nitride. The method can be used in the field of electronic components, of transducers for sensors, of optics, mechanics and micromechanics, of decorating and protecting surfaces, of motor vehicles, of aeronautics or of aerospace.

### TECHNICAL FIELD OF THE INVENTION

This invention relates to the general field of producing thin layers and more particularly to the metallisation of various substrates. It relates more particularly to a method for coating a substrate with tetragonal vanadium nitride by means of high-power pulsed magnetron sputtering and to a substrate coated with at least one layer of tetragonal vanadium nitride.

The method and substrate of the invention are particularly useful in the fields of electronic components, of transducers for sensors, of optics, of photonics, of mechanics and micro-mechanics, of decorating and protecting surfaces, of motor vehicle, of aeronautics or of aerospace.

### TECHNICAL BACKGROUND

To improve the properties of metallic, composite, polymer or other materials, particularly in terms of corrosion and/or wear resistance, the substrates are coated with a protective layer.

The coating commonly known as hard chromium has a number of physical, chemical and wear resistance properties in various environments, making it one of the most widely used multi-purpose coatings, with applications in a variety of industrial sectors (machining, land, air and space transport). Hard chromium is obtained by electrolytic chromium deposition involving the presence of hexavalent chromium (Cr⁶⁺). However, the latter has carcinogenic, mutagenic and repro-toxic (CMR) properties, which are not compatible with the REACH directive (a European Union regulation adopted to better protect human health and the environment against the risks associated with chemical substances, while promoting the competitiveness of the EU chemical industry). However, hard chromium has versatile properties that are difficult to match with a single universal solution.

The family of transition metal nitrides has a number of similar structural and functional properties which, for certain applications, could make it an alternative to hard chromium.

The ban imposed by the REACH directive on the use of hexavalent chromium (Cr⁶⁺) present during the production of electrolytic chromium or hard chromium deposition led the inventors of the present invention to study transition metal nitrides, including vanadium nitride, in order to approximate the structural and functional properties of hard chromium. Vanadium nitride was therefore explored and its tribological properties studied. Hardness, electrical resistivity, thermal conduction, etc. are all interesting properties to develop, in line with the field concerned.

Vanadium nitrides have already been studied by researchers. Different crystallographic phases of vanadium nitride are predicted by ab initio calculations.

En 1988, F. Kubel et al., Physical Review B, 1988, vol. 38, no. 18, 12908-12912, obtained the tetragonal phase of vanadium nitride at a transition temperature of 205 K (−68 °C). This metastable phase was not stabilised at temperatures above 205 K (−68 °C). What's more, the material was not a coating but a powder. The study of metastable vanadium nitride phases not present in the V-N binary phase diagram, whatever the temperature (>0 °C) and nitrogen stoichiometry, was carried out using ab initio calculations with the aim of understanding the stabilisation of these phases.

Vanadium nitrides have also been studied as hardening reinforcements for steels.

A. B. Mei et al. (Physical Review B, vol. 91, no. 5, 054101) have developed thin layers of cubic phase vanadium nitride by Direct Current Magnetron Sputtering (dcMS). The authors also used ab initio molecular dynamics calculations to study the transition from the cubic phase to the tetragonal phase occurring at 205 K in order to correlate them with analyses carried out at temperatures below 205 K using X-ray diffraction and transmission electron microscopy. There is therefore a real need for an alternative coating to hard chromium with at least equivalent physical, chemical and wear resistance properties.

In particular, there is a real need for an alternative coating to hard chromium with at least equivalent physical, chemical and wear resistance properties, and which is stable at ambient temperature (20±5 °C).

In particular, there is a real need for an alternative coating to hard chromium as described above which is compatible with the REACH directive and which is simple, effective and economical to apply and therefore industrially interesting.

### SUMMARY OF THE INVENTION

The present invention relates to a method for coating a substrate with tetragonal vanadium nitride by means of high-power pulsed magnetron sputtering, characterised in that the coating of the substrate is carried out in a deposition chamber in which the vanadium is in the form of a solid vanadium target, facing the substrate to be coated,

the coating method used
at a pressure of between 0.1 and 20 Pa,

and
at a temperature between room temperature (20±5 °C) and 900 °C, and
in an atmosphere containing a mixture of nitrogen and argon with a nitrogen content of between 5 and 99%,

the polarisation of the target being controlled during deposition of the coating by imposing on it a superposition of a DC polarisation at a potential (Vc) greater than 0 and less than or equal to −900V and a pulsed polarisation, the pulses of which have a potential (Vp) between −1200 and −100 V.

The polarisation of the target can be maintained for between 10 and 900 μs. The polarisation of the target can be achieved at a frequency of between 100 and 9000 Hz.

The device for carrying out deposition by high-power pulsed magnetron sputtering, comprising a deposition chamber illustrated in FIG. 1 and described in detail in application FR 3 097 237, is entirely suitable for carrying out the method of the invention.

As already indicated, the tetragonal crystallographic phase of vanadium nitride was predicted by calculation as a metastable phase, but could never be stabilised or observed at room temperature (20±5 °C). The inventors have succeeded in obtaining and stabilising the tetragonal crystallographic phase of vanadium nitride at room temperature (20±5°C) and in characterising it, thanks to the use and control of the parameters of a High Power Impulse Magnetron Sputtering (HiPIMS) method, which has never been done before. In the high-power pulsed magnetron sputtering (HiPIMS) technique, the target is specially polarised to form a coating of tetragonal vanadium nitride, which is a satisfactory material in terms of its physical, chemical and wear resistance properties in various environments, as a replacement for hard chromium.

The invention also relates to a substrate coated with at least one thin layer of tetragonal vanadium nitride.

The method can be used to coat the substrate with one or more thin layers of tetragonal vanadium nitride, depending on the chosen operating conditions. When the substrate is coated with several layers, these layers can possibly be detected according to their microstructure. In HiPIMS, the layers will be dense and the distinction between two layers can be made, for example, by scanning electron microscopy (SEM). It is also possible to coat the substrate with one or more thin layers of tetragonal vanadium nitride and/or one or more layers of different materials and/or vanadium nitride of different phases.

The high-power pulsed magnetron sputtering (HiPIMS) technology implemented by the method of the invention makes it possible to develop dense, homogeneous and defect-free coatings, the microstructure and chemical composition of which are perfectly controlled. The method of the invention adds new modifiable parameters such as pulse intensity, pulse duration, frequency, etc. to those usually optimised for magnetron sputter deposition, resulting in the stabilisation of new metastable crystalline phases. Thus the method of the invention is particularly interesting because it enables the tetragonal vanadium nitride phase to be stabilised at room temperature (20±5 °C) using high-power pulsed magnetron sputtering (HiPIMS). This phase, not predicted in the phase diagram and observed only once experimentally in powder during a phase change at low temperature (205 K) of the cubic phase, could never be characterised at room temperature (20±5 °C).

### BRIEF DESCRIPTION OF THE FIGURES

Other features and advantages of the invention will become apparent from the following detailed description and the attached figures.

FIG. 1 schematically represents a deposition chamber in which a method is carried out for coating a substrate with tetragonal vanadium nitride by means of high-power pulsed magnetron sputtering according to one embodiment of the invention.

FIG. 2 shows a PANalytical X'Pert Pro X-ray diffractogram of 316L stainless steel substrates measuring 2.5 cm×2.5 cm and 500 μm thick, coated with a layer of tetragonal vanadium nitride according to the method of the invention.

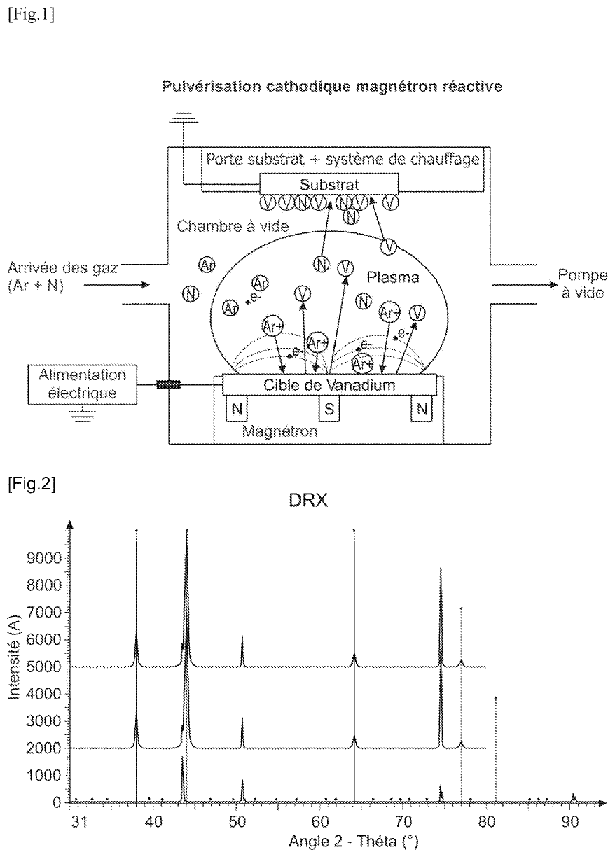

Starting from the bottom, the first diffractogram is that of the bare substrate, i.e. the part on which the coating is applied. The middle and top diffractograms are the diffractograms of two depositions of tetragonal VN made one month apart. By comparing the diffraction peaks and angles, we can observe the reproducibility of the invention's method.

The X-rays penetrate the sample (i.e. substrate+coating) to a depth greater than that of the coating. The diffractograms of the sample (middle and top diffractograms) therefore show peaks corresponding to the coating and peaks corresponding to the substrate. The diffractogram of the uncoated metal substrate enables to recognise the peaks of the substrate and the peaks of the coating on the diffractogram of the sample.

### DETAILED DESCRIPTION OF THE INVENTION

The present invention relates to a method for coating a substrate with tetragonal vanadium nitride by means of high-power pulsed magnetron sputtering, characterised in that the coating of the substrate is carried out in a deposition chamber in which the vanadium is in the form of a solid vanadium target, facing the substrate to be coated,

the coating method used
at a pressure of between 0.1 and 20 Pa,

and
at a temperature between room temperature (20±5 °C) and 900 °C, and
in an atmosphere containing a mixture of nitrogen and argon with a nitrogen content of between 5 and 99%,

the polarisation of the target being controlled during deposition of the coating by imposing on it a superposition of a DC polarisation at a potential (Vc) greater than 0 and less than or equal to −900V and a pulsed polarisation, the pulses of which have a potential (Vp) between −1200 and −100 V.

In the context of this invention, the term “solid vanadium target” refers to a vanadium target with a purity of at least 99.5% vanadium by mass.

The polarisation of the target can be achieved at a frequency of between 100 and 9000 Hz.

In one embodiment, the coating method takes place at a pressure of 1 Pa.

Although an atmosphere containing a mixture of nitrogen and argon as described above is preferred, it may be possible to carry out the coating method of the invention in a nitrogen atmosphere mixed with other plasma-forming gases known to those skilled in the art.

In the context of the invention, the expression “between . . . and . . . ” is to be understood as including the limits.

In the context of the invention, the expression “greater than . . . or less than . . . ” should be understood as not including the limits.

The coating is in the form of a thin layer.

The thin layer is produced in a low-pressure deposition chamber with a base vacuum of less than 10-4 mbar, preferably less than 10-6 mbar. The vanadium is present in the deposition chamber in the form of a solid vanadium target, facing the substrate to be coated. The target is the cathode. The substrate to be coated forms an anode.

The substrate is maintained at a temperature between room temperature (20±5 °C) and 900 °C throughout the deposition process.

During deposition, a plasma gas mixture as described above is introduced into the deposition chamber. The target is in contact with a cooled cathode coupled to permanent magnets, while the substrate is grounded or optionally positively biased or left at floating potential. A potential difference is imposed between the two electrodes, enabling the breakdown voltage of the gas or gas mixture to be reached in order to initiate a low-pressure plasma, i.e. a pressure of between 1.10⁻⁴ and 1 mbar, in particular between 10⁻³ and 5.10⁻¹ mbar during deposition.

In addition to the DC electric field (from 0to −900 V, greater than 0 and less than or equal to −900V in one embodiment, or from −100 to −600V in another embodiment), the generator transmits a high-voltage pulsed current. The voltages used are between −1200 and −100 V, or −1000 and −500 V in another embodiment. The voltage peaks are maintained for durations of between 10 and 900 μs or between 50 and 400 μs in another embodiment, and frequencies of 100 and 9000 Hz or 100 to 5000 Hz in another embodiment.

As mentioned previously, the coating method takes place in an atmosphere containing nitrogen mixed with argon, with a nitrogen content of between 5 and 99%.

The thickness of each tetragonal vanadium nitride/coating layer deposited on the substrate can be between 5 nm and 15 μm. When the coating is in the form of a multilayer, the thickness of the multilayer can be between 10 nm and 100 μm, for example.

The diffractograms of 316L stainless steel substrates with dimensions of 2.5 cm×2.5 cm and a thickness of 500 ×m, coated with a layer of stabilised tetragonal vanadium nitride and obtained by the method of the invention, carried out using a PANalytical X'Pert Pro X-ray diffractometer, clearly show the characteristic peaks of tetragonal vanadium nitride as shown in FIG. 2, thus confirming that the parameters of the method of the invention described above enable a 1 μm thick coating to be obtained by the method of the invention based on the use of HiPIMS technology to stabilise the tetragonal phase of vanadium nitride.

The invention also relates to a substrate coated with at least one thin layer of tetragonal vanadium nitride.

The method can be used to coat a wide variety of substrates, depending on the application, as long as they can withstand a temperature of 40 °C.

The substrate can be metal, ceramic, composite, elastomer, glass, metallic glass, plastic or a fabric.

In one embodiment, the substrate is a stainless steel, such as for example 316L stainless steel.

In one embodiment, the substrate is an aircraft part, such as an aircraft landing gear part or an aircraft engine turbine part.

In one embodiment, the substrate is a gas turbine or marine turbine part.

The method of the invention is of particular interest in the field of electronic components, of transducers for sensors, of optics, of photonics (i.e. lasers, light-emitting diodes, optical fibres, optical modulators, optical amplifiers or photonic crystals, lenses, prisms and gratings), of mechanics and micro-mechanics, of decorating and protecting surfaces, of motor vehicles, of aeronautics or of aerospace.

Another object of the invention is therefore the use of the method of the invention for the manufacturing of electronic components, transducers for sensors, optical components, mechanical and micro-mechanical components, components for decorating and protecting surfaces, components for the automotive, aeronautical or aerospace industries.

### EXAMPLES

The coating is deposited on 316L stainless steel substrates. The substrate is first cleaned by immersion in a beaker of boiling isopropanol. The base vacuum of the chamber reached before deposition is 3.0E-6 T. The plasma is ignited at 5 Pa in an Argon/Diazote mixture. The imposed voltage and current are−1000V and 200 mA respectively, with a DC background of −50 V and 10 mA. The frequency and width of the high-power pulse (HiPIMS) are 100 Hz and 200 μs respectively. The pressure is then reduced to 1 Pa. The chamber is preheated to 400 °C with an Ar/N₂ mixture at 1 Pa, 40 sccm Argon, 5 sccm Diazote. The Ar/N₂ mixture can be described by the percentage of N₂ in the total volume of gas [Ar+N₂]. It is 5/(40+5)=11%. The ratio can, however, be a good way of describing the method (N₂ ratio=N₂ flow/Ar flow). The diazote ratio is 12.5. The plasma is stabilised at this point in the method for 15 minutes, then the substrate is brought to face the Vanadium target (purity greater than or equal to 99.9%). The deposition lasts 3 hours.

The thickness of the coating was determined by Scanning Electron Microscopy (SEM JEOL 6360 A) and the crystal structure was determined by X-ray Diffraction (DRX PANalytical X'Pert Pro).

1. A method for coating a substrate with tetragonal vanadium nitride by high-power pulsed magnetron sputtering, wherein the coating of the substrate is carried out in a deposition chamber in which the vanadium is in the form of a solid vanadium target facing the substrate to be coated, the coating method comprising:
coating the substrate:
at a pressure of between 0.1 and 20 Pa;
at a temperature between room temperature (20±5 °C) and 900 °C; and
in an atmosphere containing a mixture of nitrogen and argon with a nitrogen content of between 5 and 99%; and
polarizing the vanadium target, wherein polarization of the target is controlled during the coating by imposing thereon a superposition of a DC polarization at a first potential greater than 0 and less than or equal to −900V and a pulsed polarization, the pulses of which have a second potential between −1200 and −100 V.

2. The method according to claim 1, wherein the method takes place at a pressure of 1 Pa.

3. The method according to claim 1, wherein the polarization of the vanadium target is achieved at a frequency of between 100 and 9000 Hz.

4. The method according to claim 1, wherein the first potential is between −100 and −600V.

5. The method according to claim 1, wherein the second potential is between −1000 and −500 V.

6. The method according to claim 1, wherein the substrate is coated with one or more thin layer(s) of tetragonal vanadium nitride, the thickness of each layer being between 5 nm and 15 μm.

7. The method according to claim 6, wherein the coating is in the form of a multilayer, the thickness of the multilayer being between 10 and 100 μm.

8. The method according to claim 1, wherein the vanadium is in the form of a solid vanadium target with a purity of at least 99.5% vanadium by mass.

9. A use of the method according to claim 1, comprising a use for manufacturing of electronic components, transducers for sensors, optical components, mechanical and micro-mechanical components, components for decorating and protecting surfaces, components for the automotive, aeronautical, or aerospace industries.

10. A substrate coated with at least one thin layer of tetragonal vanadium nitride by a method according to claim 1, wherein the substrate is:
an aircraft landing gear part;
an aircraft engine turbine part;
a gas turbine or marine turbine part.
